(19) United States
(12) Patent Application Publication
(10) Pub. No.: US 2025/0056885 A1
(43) Pub. Date: Feb. 13, 2025

(54) SEMICONDUCTOR DEVICE, OP-AMP AND DISPLAY DEVICE

(71) Applicant: Japan Display Inc., Tokyo (JP)

(72) Inventor: Yoshinori AOKI, Tokyo (JP)

(73) Assignee: Japan Display Inc., Tokyo (JP)

(21) Appl. No.: 18/780,701

(22) Filed: Jul. 23, 2024

(30) Foreign Application Priority Data
Aug. 7, 2023 (JP) 2023-128874

(51) Int. Cl. H01L 27/12; H03F 3/45

(52) U.S. Cl. CPC H01L 27/1233; H01L 27/124; H03F 3/45273

(57) ABSTRACT

The semiconductor device includes a first transistor including a first gate electrode, a second transistor including a second gate electrode electrically connected to the first gate electrode and a source electrode electrically connected to a drain electrode of the first transistor. The first transistor includes a first channel width and a first gate length. The second transistor includes a second channel width and a second gate length. A value obtained by dividing the second channel width by the second gate length is greater than or equal to a value obtained by dividing the first channel width by the first gate length.

### CROSS-REFERENCE TO RELATED APPLICATION

This application claims the benefit of priority to Japanese Patent Application No. 2023-128874 filed on Aug. 7, 2023, the entire contents of which are incorporated herein by reference.

### FIELD

An embodiment of the present invention relates to a semiconductor device, an OP-AMP and a display device.

### BACKGROUND

Various display devices have been implemented and popularized in televisions, smartphones, and the like. For example, the display device includes a plurality of pixels. In addition, the display device may include an operational amplifier (OP-AMP) that amplifies a signal for driving the plurality of pixels, and an OP-AMP that generates a power supply voltage used in the display device, or the like. For example, the display device includes the OP-AMP to enable an operation using a signal and a power supply voltage with little fluctuation in voltage or frequency.

For example, Japanese laid-open patent publication No. 2013-083804 discloses a liquid crystal display device including an amplification circuit including the OP-AMP.

### SUMMARY

A semiconductor device includes a first transistor including a first gate electrode, and a second transistor including a second gate electrode electrically connected to the first gate electrode and a source electrode electrically connected to a drain electrode of the first transistor. The first transistor includes a first channel width and a first gate length. The second transistor includes a second channel width and a second gate length. A value obtained by dividing the second channel width by the second gate length is greater than or equal to a value obtained by dividing the first channel width by the first gate length.

An OP-AMP includes a plurality of the semiconductor devices. The semiconductor device includes a first transistor including a first gate electrode, and a second transistor including a second gate electrode electrically connected to the first gate electrode and a source electrode electrically connected to a drain electrode of the first transistor. The first transistor includes a first channel width and a first gate length. The second transistor includes a second channel width and a second gate length. A value obtained by dividing the second channel width by the second gate length is greater than or equal to a value obtained by dividing the first channel width by the first gate length.

A display device includes the OP-AMP and a plurality of pixels electrically connected to the OP-AMP. The OP-AMP includes a plurality of the semiconductor devices. The semiconductor device includes a first transistor including a first gate electrode, and a second transistor including a second gate electrode electrically connected to the first gate electrode and a source electrode electrically connected to a drain electrode of the first transistor. The first transistor includes a first channel width and a first gate length. The second transistor includes a second channel width and a second gate length. A value obtained by dividing the second channel width by the second gate length is greater than or equal to a value obtained by dividing the first channel width by the first gate length.

### BRIEF DESCRIPTION OF DRAWINGS

FIG. 1 is a schematic diagram showing a configuration of a constant current source including a semiconductor device according to a first embodiment of the present invention.

FIG. 2 is a diagram for explaining an example of a voltage applied to each terminal of the constant current source according to the first embodiment of the present invention.

FIG. 3 is a diagram showing an example of electrical characteristics of a constant current source according to the first embodiment of the present invention.

FIG. 4 is a graph showing actual measurement results of electrical characteristics of the constant current source according to the first embodiment of the present invention.

FIG. 5 is a diagram showing an example of a layout of a semiconductor device according to the first embodiment of the present invention.

FIG. 6 is a cross-sectional view showing a cross-sectional structure along A1-A2 of FIG. 5.

FIG. 7 is a diagram showing an example of a layout of a semiconductor device according to the first embodiment of the present invention.

FIG. 8 is a diagram showing an example of a layout of a semiconductor device according to the first embodiment of the present invention.

FIG. 9 is a circuit diagram showing a configuration of an operational amplifier (OP-AMP) according to a second embodiment of the present invention.

FIG. 10 is a plan view showing a configuration of a display device according to a third embodiment of the present invention.

FIG. 11 is a plan view showing a configuration of a display device according to the third embodiment of the present invention.

### DESCRIPTION OF EMBODIMENTS

In order for an operational amplifier (OP-AMP) to generate a signal and a power supply voltage with little fluctuation in voltage or frequency, for example, a constant current source included in the OP-AMP needs to generate a current with little fluctuation.

In view of the above, an object of an embodiment of the present invention is to provide a semiconductor device capable of generating a current with little fluctuation, an OP-AMP including the semiconductor device, and a display device including the OP-AMP.

An example of the semiconductor device capable of generating a current with little fluctuation, the OP-AMP including the semiconductor device, and the display device including the OP-AMP according to an embodiment of the present invention will be described below with reference to the drawings and the like. However, the present invention can be implemented in many different aspects, and should not be construed as being limited to the description of the embodiments exemplified below. In order to make the description clearer, the drawings may be schematically represented with respect to the width, thickness, shape, and the like of each part as compared with the actual embodiment, but the drawings are merely examples, and do not limit the interpretation of the present invention. In addition, in the present specification and the drawings, elements similar to those described previously with respect to the above-described figures are denoted by the same reference signs (or reference signs denoted by a, b, and the like) and detailed description thereof may be omitted as appropriate. Furthermore, the terms “first” and “second” with respect to each element are convenient signs used to distinguish each element, and do not have any further meaning unless otherwise specified.

In this specification, a member or region is “above (or below)” another member or region, including, without limitation, the case where it is directly above (or below) the other member or region, but also the case where it is above (or below) the other member or region, that is, the case where another component is included between above (or below) the other member or region.

In the present specification, a direction D1 intersects a direction D2, and a direction D3 intersects the direction D1 and the direction D2 (D1 D2 plane). The direction D1 is referred to as a first direction, the direction D2 is referred to as a second direction, and the direction D3 is referred to as a third direction. For example, the direction D1, the direction D2, and the direction D3 correspond to an X direction (x direction), a Y direction (y direction), and a Z direction (z direction).

In the case where the terms “same” and “identical” are used in the present specification, “same” and “identical” may include errors within a range of design.

### First Embodiment

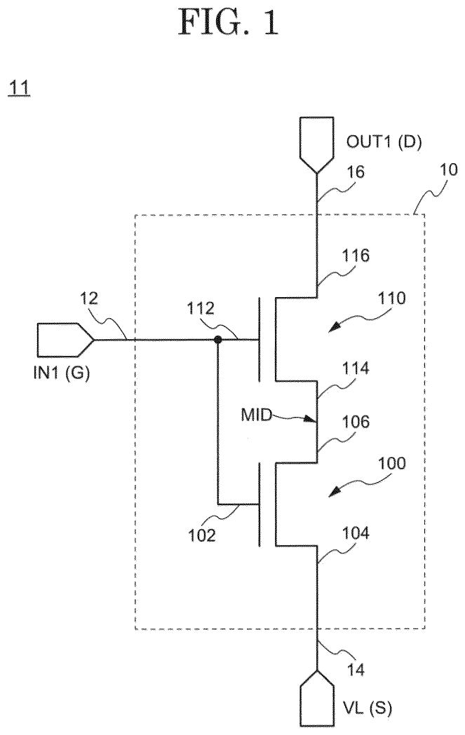

A constant current source 11 including a semiconductor device 10 will be described with reference to FIG. 1 to FIG. 8. For example, the constant current source 11 is a power supply circuit that keeps an output current constant regardless of the magnitude of the connected load.

### [1-1. Configuration of Semiconductor Device 10]

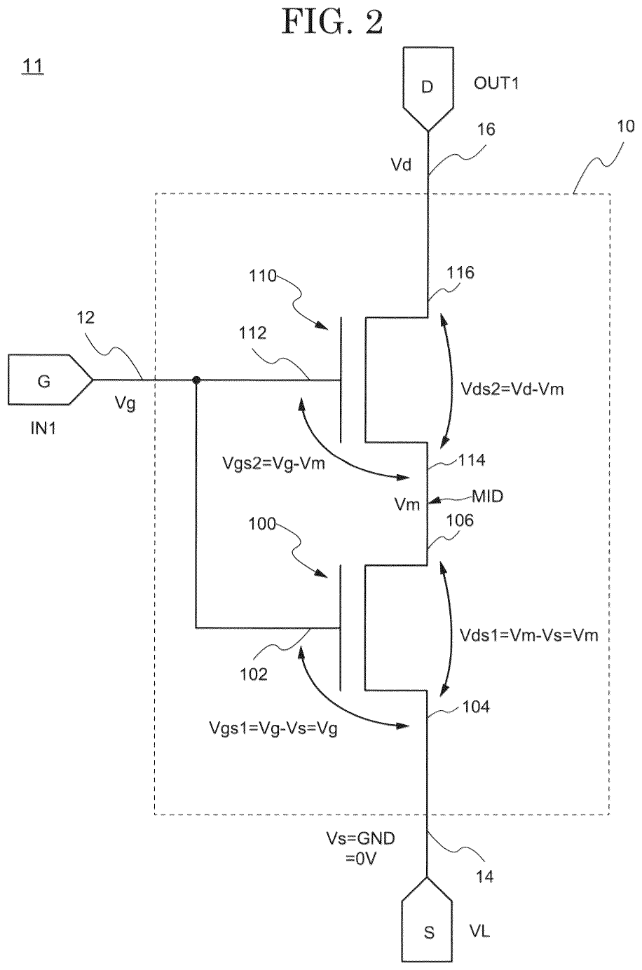

A configuration of the semiconductor device 10 and the constant current source 11 including the semiconductor device 10 will be described with reference to FIG. 1 and FIG. 2. FIG. 1 is a circuit diagram showing a configuration of the constant current source 11 including the semiconductor device 10. FIG. 2 is a diagram for explaining an example of a voltage applied to each terminal of the constant current source 11.

As shown in FIG. 1, the constant current source 11 includes the semiconductor device 10. The semiconductor device 10 includes a gate electrode 102, a first transistor 100 including a source electrode 104 and a drain electrode 106, and a second transistor 110 including a gate electrode 112 electrically connected to the gate electrode 102, a source electrode 114 electrically connected to the drain electrode 106, and a drain electrode 116. The drain electrode 106 and the source electrode 114 are connected to an intermediate electrode MID. The intermediate electrode MID may be referred to as an intermediate node. In addition, in the present specification and the drawings, the functions of the source and the drain of each electrode may be interchanged depending on the voltages supplied (applied) to the source electrode and drain electrode of the transistor.

The gate electrode 102 and the gate electrode 112 are electrically connected to an input signal line 12. The source electrode 104 is electrically connected to a first voltage supply wiring 14. The drain electrode 116 is electrically connected to an output signal line 16.

The names of the terminals do not limit the input and output of the constant current source 11. The input and output to the constant current source 11 may be switched depending on a voltage of an output signal OUT1 and a voltage of an input signal IN1.

The input signal IN1 is supplied to the input signal line 12, a common voltage VL is supplied to the first voltage supply wiring 14, and the output signal OUT1 is output to the output signal line 16. For example, the common voltage VL may be a ground voltage, 0 V, a voltage VSS, a grounding voltage, a reference voltage in a device using the common voltage VL, or the like.

As shown in FIG. 2, the semiconductor device 10 and the constant current source 11 including the semiconductor device 10 may be considered to include one transistor including two gate electrodes (so-called double gate). In the constant current source 11, the output signal line 16 may be regarded as a drain terminal D, the input signal line 12 may be regarded as a gate terminal G, and the first voltage supply wiring 14 may be regarded as a source terminal S.

For example, a voltage Vg is applied to the gate terminal G, the gate electrode 102, and the gate electrode 112, a voltage Vs is applied to the source terminal S and the source electrode 104, a voltage Vd is applied to the drain terminal D and the drain electrode 116, and a voltage Vm is applied to the intermediate electrode MID. For example, the voltage Vs is 0 V.

A gate-source voltage Vgs1 applied between the gate electrode 102 and the source electrode 104 of the first transistor 100 is the voltage Vg (voltage Vg−voltage Vs=voltage Vg−0). A drain-source voltage Vds1 applied between the drain electrode 106 and the source electrode 104 of the first transistor 100 is the voltage Vm (voltage Vm−voltage Vs=voltage Vm−0).

A gate-source voltage Vgs2 applied between the gate electrode 112 and the source electrode 114 of the second transistor 110 is voltage Vg−voltage Vm. A drain-source voltage Vds2 applied between the drain electrode 116 and the source electrode 114 of the second transistor 110 is voltage Vd−voltage Vm.

### [1-2. Comparison of Electrical Characteristics]

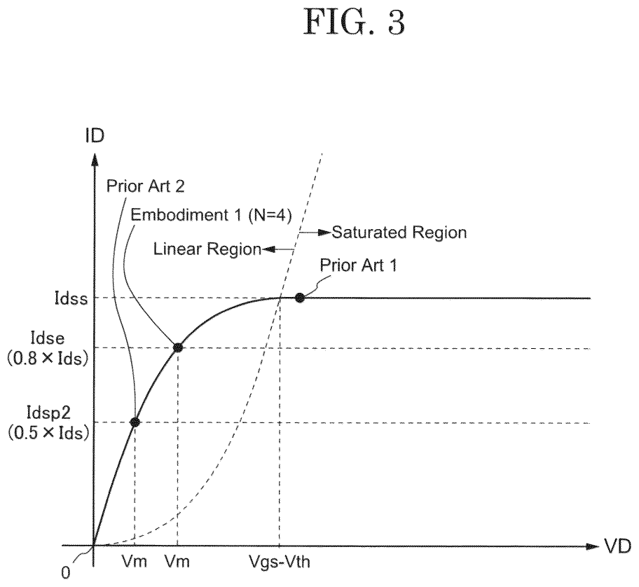

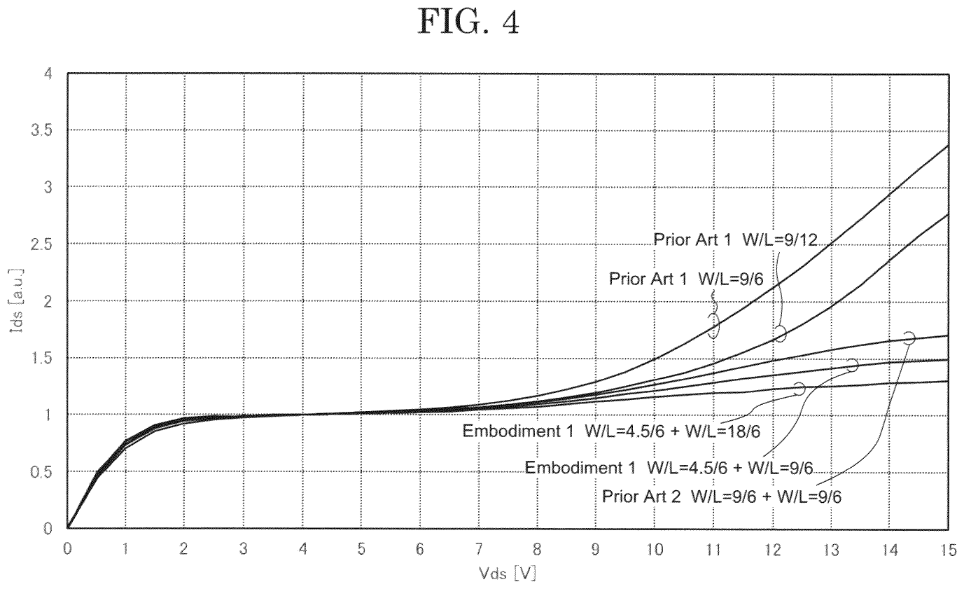

Electrical characteristics of the constant current source 11 will be described with reference to FIG. 3 and FIG. 4. FIG. 3 is a diagram showing an example of the electrical characteristics of the constant current source 11 including the semiconductor device 10. FIG. 4 is a graph showing actual measurement results of the semiconductor device 10. In FIG. 3 and FIG. 4, electric characteristics of a single-gate constant current source of Comparative Example 1 (Prior Art 1) and electric characteristics of a double-gate constant current source of Comparative Example 2 (Prior Art 2) are also shown in the electric characteristics of the constant current source 11 for reference. Configurations that are the same as or similar to those in FIG. 1 and FIG. 2 will be described as necessary.

Table 1 shows a channel width and a gate length of the transistor included in the single-gate constant current source of Comparative Example 1, a channel width and a gate length of each of the first transistor and the second transistor included in the double-gate constant current source of Comparative Example 2, a channel width and a gate length of the first transistor 100 included in the constant current source 11 of the present embodiment (Embodiment 1), and a channel width and a gate length of the second transistor 110 included in the constant current source 11 of the present embodiment (Embodiment 1).

TABLE 1

| | | Channel | Gate |
|---|---|---|---|
| | | width [μm] | length [μm] |
| Comparative Example1 | Transistor | W | L |
| (single-gate constant | | | |
| current source) | | | |
| Comparative Example 2 | First transistor | W | L |
| (double-gate constant current | Second trnasistor | W | L |
| Embodiment 1 | First transistor | W1 | L1 |
| | | (=(1 + N)/N × W3) | |
| | Second trnasistor | W2 | L2 |
| | | (=N × W1 = (1 + N) × W3) | (=L1) |

As shown in Table 1, for example, a channel width and a gate length of a transistor of Comparative Example 1 are a channel width W and a gate length L. In addition, for example, the channel width and the gate length of each of the first transistor and the second transistor of Comparative Example 2 are the channel width W and the gate length L. On the other hand, for example, the channel width and the gate length of the first transistor 100 of the first embodiment are a channel width W1 and a gate length L1, and for example, the channel width and the gate length of the second transistor 110 of the first embodiment are a channel width W2 and a gate length L2. In addition, the gate length L1 is the same as the gate length L2 in the first embodiment. The channel width W1 may be referred to as a first channel width, the channel width W2 may be referred to as a second channel width, the gate length L1 may be referred to as a first gate length L1, and the gate length L2 may be referred to as a second gate length.

In addition, the channel width W1 is represented by the following formula (1), and the channel width W2 is represented by the following formula (2) by using a numerical valueN(N >0) and a reference channel width W3.

$$W 1 = \frac{( 1 + N )}{N} W 3 \qquad ( 1 )$$

$$W 2 = ( 1 + N ) W 3 \qquad ( 2 )$$

In the case where the thin film transistor operates in a saturated region, a drain current Idss represented by the following formula (3) flows from the drain terminal to the source terminal of the thin film transistor. In the case where the thin film transistor operates in a linear region, a drain current Idsl represented by the following formula (4) flows from the drain terminal to the source terminal of the thin film transistor.

$$Idss = \frac{μ \cdot {C}_{ox} \cdot W}{2 \cdot L} \cdot {( {V}_{gs} - {V}_{th} )}^{2} \qquad ( 3 )$$

$$Idsl = \frac{μ \cdot {C}_{ox} \cdot W}{L} \cdot [ ( {V}_{gs} - {V}_{th} ) \cdot {V}_{ds} - \frac{{V}_{ds}^{2}}{2} ] \qquad ( 4 )$$

In formula (3) and formula (4), a capacitance Cₒₓ is a capacitance of the gate insulating film per unit area, a mobility μ is a mobility of an electron, and a threshold voltage Vₜₕ is the threshold voltage, the channel width W, and the gate length L of the thin film transistor. Similar to the constant current source 11 described with reference to FIG. 2, the voltage Vgs is the gate-source voltage of the thin film transistor, and the voltage Vds is the drain-source voltage of the thin film transistor.

### 1-2-1. Electrical Characteristics of Comparative Example 1

Consider the case where the transistor of the single-gate constant current source of Comparative Example 1 operates in the saturated region. In this case, the drain current Idss represented by formula (3) flows from the drain terminal to the source terminal of the thin film transistor. That is, the single-gate constant current source can flow the drain current Idss represented by formula (3).

For example, FIG. 3 is a diagram showing a dependency of the drain current ID with respect to the drain voltage VD of the single-gate constant current source of Comparative Example 1. At a border between the linear region and the saturated region, the source-drain voltage Vds (VD) is the same as the difference between the voltage Vgs and the threshold voltage Vₜₕ, that is, voltage Vgs−voltage Vₜₕ.

As shown in FIG. 3, the drain current Idss of Comparative Example 1 (Prior Art 1) is ideally a current that does not depend on the drain voltage VD, and is called a so-called saturated current, constant current, or the like.

FIG. 4 is a graph showing actual measurement results indicating the dependency of the drain current ID with respect to the drain voltage VD. The normalized drain current Ids (Ids [a.u]) shown in FIG. 4 is a drain current obtained by normalizing the drain current Ids when the gate-source voltage Vgs is 4 V by the drain current when the drain-source voltage Vds is 4 V.

As shown in FIG. 4, in the constant current source when the channel width W/the gate length L=9 μm/6 μm of Comparative Example 1 (Prior Art 1), the drain voltage rapidly increases as the drain voltage Vds increases, and so-called kink characteristics are not suppressed. In addition, even if the gate length L is 12 μm, which is twice the gate length L, the kink characteristics are not sufficiently suppressed.

### 1-2-2. Electrical Characteristics of Comparative Example 2

Consider the case where the transistor of the double-gate constant current source of Comparative Example 2 operates in the saturated region. In this case, the drain current Idss represented by formula (3) flows from the drain terminal to the source terminal of the thin film transistor. That is, the single-gate constant current source can flow the drain current Idss represented by formula (3).

Consider the case where the double-gate constant current source of Comparative Example 2 operates in the same manner as the single-gate constant current source transistor of Comparative Example 1. In this case, the second transistor operates in the saturated region, and the drain current Idss represented by formula (3) flows from the drain terminal of the second transistor to the source terminal. In addition, the first transistor operates in the linear region, and the drain current Idsl represented by formula (4) flows from the drain terminal to the source terminal of the first transistor.

In addition, similar to the constant current source 11 described with reference to FIG. 2, the voltage Vs of the double-gate constant current source of Comparative Example 2 is 0 V, the voltage Vgs of formula (3) is voltage Vg−voltage Vm, and the voltage Vds is voltage Vd−voltage Vm. In addition, the voltage Vgs in formula (4) is the voltage Vg, and the voltage Vds is the voltage Vm.

The channel width W and the gate length L of the first transistor and the second transistor of Comparative Example 2 are the same as the channel width W and the gate length L of the transistor of the single-gate constant current source. Therefore, in formula (3) and formula (4), Cₒₓ is the capacitance of the gate insulating film per unit area, μ is the mobility of the electron, and Vₜₕ is the threshold voltage of each of the first transistor and the second transistor.

In addition, the current flowing through the first transistor and the second transistor of the double-gate constant current source is the same, and the drain current Idss is the same as the drain current Idsl. When a drain current Idsp2 is calculated using formula (3) and formula (4) assuming that formula (3) and formula (4) are equal, the drain current Idsp2 can be represented by formula (5). That is, the double-gate constant current source can flow the drain current Idsp2 represented by formula (5).

$$Idsp 2 = \frac{1}{2} \cdot \frac{μ \cdot {C}_{ox} \cdot W}{2 \cdot L} \cdot {( {V}_{gs} - {V}_{th} )}^{2} \qquad ( 5 )$$

As shown in FIG. 4, the constant current source when the channel width W/the gate length L=9 μm/6 μm of the first transistor and the channel width W/the gate length L=9 μm/6 μm of the second transistor of Comparative Example 2 (Prior Art 2) can suppress the kink characteristics more than the constant current source of Comparative Example 1.

On the other hand, the drain current Idsp2 shown in formula (5) is ½ (half) of the drain current Idss shown in formula (3). That is, as shown in FIG. 3, the double-gate constant current source of Comparative Example 2 can only flow half of the current of the single-gate constant current source of Comparative Example 1.

### [1-2-3. Electrical Characteristics of Constant Current Source 11]

Based on formula (1) and formula (2), the channel width W2 of the second transistor 110 of the constant current source 11 is N times the channel width W1 of the first transistor 100. The voltage Vm of the intermediate electrode MID becomes larger than the voltage Vm of the intermediate electrode MID of Comparative Example 2 by making the channel width W2 of the second transistor 110 larger than the channel width W1 of the first transistor 100. As a result, the first transistor 100 can operate in the linear region that is closer to the saturated region.

As in Comparative Example 2, assuming that the currents flowing through the first transistor 100 and the second transistor 110 of the constant current source 11 are the same, the voltage Vm and a drain current Idse of the constant current source 11 are calculated. The voltage Vm can be represented by formula (6), and the drain current Idse can be represented by formula (7). That is, the constant current source 11 can flow the drain current Idse represented by formula (7).

$$V m = ( {V}_{gs} - {V}_{th} ) \cdot ( 1 - \frac{\sqrt{( 1 + N )}}{( 1 + N )} ) \qquad ( 6 )$$

$$Idse = \frac{1}{2} \cdot \frac{μ \cdot {C}_{ox} \cdot W}{2 \cdot L} \cdot {( {V}_{gs} - {V}_{th} )}^{2} \cdot \frac{N}{( 1 + N )} \qquad ( 7 )$$

The drain current Idse of the constant current source 11 is N/(1+N) times the drain current Idss shown in formula (3).

In addition, the difference between the drain current Idse and the drain current Idss (amount of change in the drain current) with the increase in the voltage Vm is 1−N/(1+N)=1/(1+N). When the channel width W/the gate length L is set to 1 unit, and the drain current Idse is adjusted to be equal to the drain current Idss, an effect by the amount of change in the drain current is 1/N. That is, the amount of change in the drain current is 1+1/N=(1+N)/N.

This means that in the case where the numerical value N is 1 unit of the channel width W/the gate length L, formula (1) and formula (2) indicate that the channel width/the gate length L of the first transistor 100 and the channel width/the gate length L of the second transistor 110 are (1+N)/N:(1+N). That is, a value obtained by dividing the channel width W2 by the second gate length L2 is greater than or equal to a value obtained by dividing the channel width W1 by the first gate length L1. For example, in the case of N=2, the amount of change in the drain current is 1.5 times, and in the case of N=4, the amount of change in the drain current is 1.25 times.

For example, in the case of N=1, a ratio (W ratio) of the channel width W1 of the first transistor 100 to the channel width W2 of the second transistor 110 is 2:2. For example, in the case where the reference channel width W3 is 4 μm (W3=4), the channel width W1 of the first transistor 100 is 8 μm, and the channel width W2 of the second transistor 110 is 8 μm. In addition, in the case of N=4, the channel width W1 of the first transistor 100 and the channel width W2 of the second transistor 110 are 1.25:5. For example, in the case where the reference channel width W3 is 4 μm (W3=4), the channel width W1 of the first transistor 100 is 5 μm, and the channel width W2 of the second transistor 110 is 20 μm. In the case where the reference channel width W3 is 4 μm, the W ratio, the channel width W1 of the first transistor 100, and the channel width W2 of the second transistor 110 are shown in Table 2 as an example. In addition, the channel length L1=L2 is, for example, 6 μm. The reference channel width W3, the channel length L1, and the channel length L2 described herein are examples, and the reference channel width W3, the channel length L1, and the channel length L2 are not limited to the numerical values described herein. The numerical values of the reference channel width W3, the channel length L1, and the channel length L2 may be appropriately set so as to satisfy each formula depending on the application and specifications of the semiconductor device 10 or the constant current source 11 including the semiconductor device 10.

TABLE 2

| | | | Amount of |
|---|---|---|---|
| W | Channel width W1 | Channel width W2 | change |
| ratio | (=((1 + N)/N) × W3) [μm] | (=((1 + N) × W3) [μm] | in drain |
| (=N) | ※W3 = 4 | ※W3 = 4 | current |
| 1 | 8 (=2 × 4) | 8 (=2 × 4) | 2 |
| 2 | 6 (=1.5 × 4) | 12 (=3 × 4) | 1.5 |
| 3 | 5.33 (=1.33 × 4) | 16 (=4 × 4) | 1.33 |
| 4 | 5 (=1.25 × 4) | 20 (=5 × 4) | 1.25 |
| 5 | 4.8 (=1.2 × 4) | 24 (=6 × 4) | 1.2 |
| 6 | 4.67 (=1.167 × 4) | 28 (=7 × 4) | 1.167 |
| 8 | 4.5 (=1.125 × 4) | 36 (=9 × 4) | 1.125 |

The drain current Idss is an ideal saturated current, and the smaller the amount of change in the drain current, that is, the larger the numerical value N, the closer the drain current Idse of the constant current source 11 is to the ideal saturated current. That is, the drain current Idse of the constant current source 11 can be adjusted to an ideal saturated current by adjusting the numerical value N.

For example, when the reference channel width W3 is 3 μm (W3=3) and the numerical value N is 2 (N=2), the channel width W1 of the first transistor 100 is 4.5 μm, and the channel width W2 of the second transistor 110 is 9 μm. As shown in FIG. 4, the constant current source 11 of the first embodiment (Embodiment 1, N=2) can suppress the kink characteristics more than the drain current of the constant current source of Comparative Example 1 and the constant current source of Comparative Example 2.

For example, when the reference channel width W3 is 3.6 μm (W3=3.6) and the numerical value N is 4 (N=4), the channel width W1 of the first transistor 100 is 4.5 μm, and the channel width W2 of the second transistor 110 is 18 μm. As shown in FIG. 4, the constant current source 11 of the first embodiment (Embodiment 1, N=4) can suppress the kink characteristics more than the constant current source 11 in the case of N=2. That is, as the numerical value N increases, the kink characteristics of the constant current source 11 are suppressed.

When N=4, the drain current Idse shown in formula (7) is ⅘ (80%) of the drain current Idss shown in formula (3). That is, as shown in FIG. 3, the constant current source 11 of the first embodiment (Embodiment 1, N=4) can flow more current than the double-gate constant current source of Comparative Example 2.

The constant current source 11 including the semiconductor device 10 is a double-gate transistor including the first transistor 100 and the second transistor 110. The channel width W2/the gate length L2 of the second transistor 110 is larger than the channel width W1/the gate length L1 of the first transistor 100, and the saturated current characteristics of the constant current source 11 are improved as compared with the conventional constant current sources of Comparative Example 1 and Comparative Example 2. Since the constant current source 11 is a circuit capable of suppressing a sudden increase in the drain current, the constant current source 11 can improve the saturated current characteristics, and the circuit including the constant current source 11 can suppress an increase in current consumption.

### [1-3. Example of Layout and Cross-sectional Structure of Semiconductor Device 10]

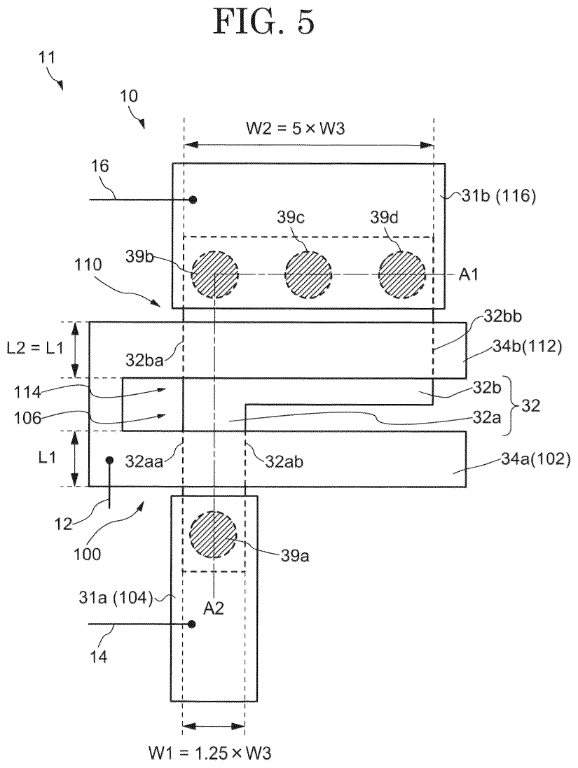

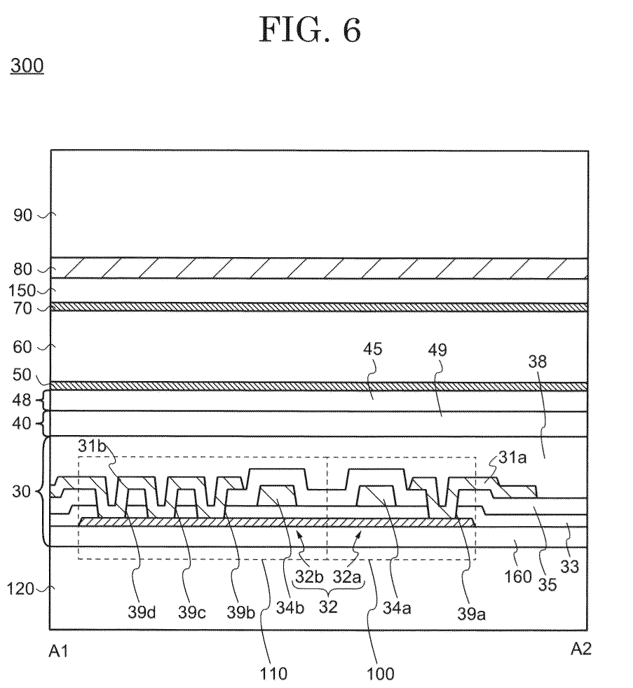

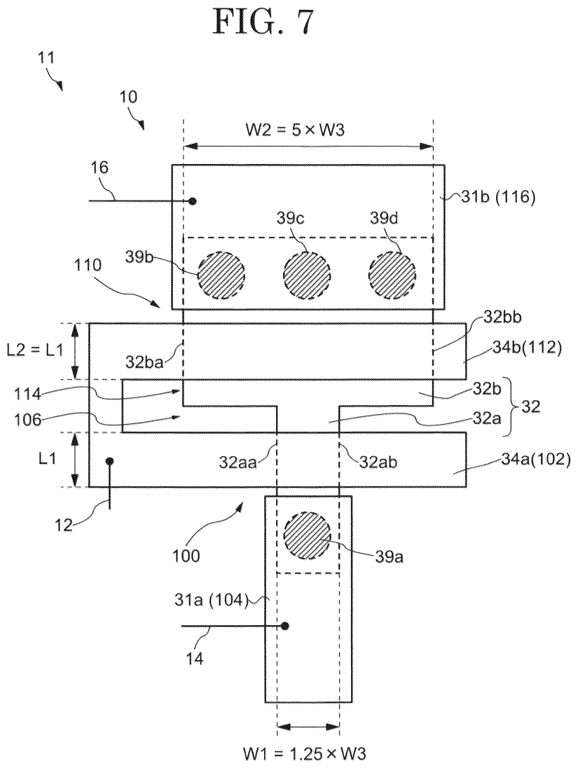

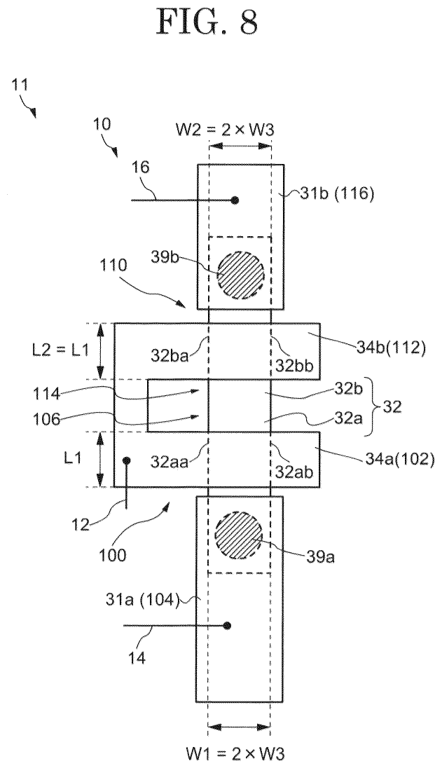

An example of a layout and cross-sectional structure of the semiconductor device 10 will be described with reference to FIG. 5 to FIG. 8. FIG. 5, FIG. 7, and FIG. 8 are diagrams showing an example of a layout of the semiconductor device 10. FIG. 6 is a cross-sectional view showing a cross-sectional structure along A1-A2 of FIG. 5. Configurations that are the same as or similar to those in FIG. 1 to FIG. 4 will be described as necessary.

Here, an example is explained in which the semiconductor device 10 and the constant current source 11 including the semiconductor device 10 are configured using the thin film transistor (TFT). The semiconductor device 10 and the constant current source 11 including the semiconductor device 10 may be configured using a transistor other than the thin film transistor. For example, the semiconductor device 10 and the constant current source 11 including the semiconductor device 10 may be configured using a transistor formed using a Si wafer, a SOI substrate, or the like.

First, an example of a layout of the semiconductor device 10 when N=4 will be described with reference to FIG. 5. FIG. 5 is a diagram showing an example of the layout of the semiconductor device 10 whenN=4, in which the channel width W1 of the first transistor 100 is 1.25×W3 (reference channel width W3) and the channel width W2 of the second transistor 110 is 5×W3. In the example shown in FIG. 5, the gate length L1 of the first transistor 100 is the same as the gate length L2 of the second transistor 110. In addition, FIG. 5 is a diagram schematically showing the output signal line 16, the input signal line 12, and the first voltage supply wiring 14, and also shows an example of the constant current source 11 including the semiconductor device 10.

As shown in FIG. 5, the first transistor 100 includes a second conductive film 31a, a first opening 39a, a first conductive film 34a, and a semiconductor film 32a. The second conductive film 31a corresponds to the source electrode 104 and the first conductive film 34a corresponds to the gate electrode 102. The semiconductor film 32a includes a part corresponding to the drain electrode 106. The second transistor 110 includes a second conductive film 31b, a plurality of first openings 39b, 39c and 39d, a first conductive film 34b, and a semiconductor film 32b. The second conductive film 31b corresponds to the drain electrode 116 and the first conductive film 34b corresponds to the gate electrode 112. The semiconductor film 32b includes a part corresponding to the source electrode 114. The drain electrode 106 and the source electrode 114 are arranged between the first conductive film 34a and the first conductive film 34b.

The semiconductor film 32a is connected to the semiconductor film 32b and forms one semiconductor film 32. A width along the direction in which the first conductive film 34a of the semiconductor film 32a extends is the channel width W1, and a width along the direction in which the first conductive film 34b of the semiconductor film 32b extends is the channel width W2. That is, the semiconductor film 32 is one pattern having two channel widths having different widths. In addition, the channel width W1 of the semiconductor film 32a includes a first end 32aa and a second end 32ab, and the channel width W2 of the semiconductor film 32b includes a first end 32ba and a second end 32bb. The first end 32aa and the first end 32ba are arranged so as to be positioned on the same straight line, and the second end 32ab and the second end 32bb are arranged so as to be positioned on different straight lines. In addition, part of the first end 32aa, part of the first end 32ba, part of the second end 32ab, and part of the second end 32bb are positioned between the first conductive film 34a and the first conductive film 34b. In addition, the semiconductor film 32 includes a channel that serves as a current path of the first transistor 100 and the second transistor 110, and may be referred to as an active layer.

For example, the semiconductor device 10 and the constant current source 11 including the semiconductor device 10 includes one transistor including two gate electrodes of the gate electrode 102 (first gate electrode) that overlaps the semiconductor film 32a (first active layer) having the channel width W1 (first channel width W1) and having the gate length L1 (first gate length) and the gate electrode 112 (second gate electrode) that overlaps the semiconductor film 32b (second active layer) formed contiguously on the semiconductor film 32a having the channel width W1 and having the gate length L2 (second gate length).

For example, the constant current source 11 including the semiconductor device 10 includes the first voltage supply wiring 14 connected to the second conductive film 31a, the input signal line 12 connected to the first conductive films 34a and 34b, and the output signal line 16 connected to the second conductive film 31b.

For example, in the case where N=4 and the reference channel width W3 is 4 μm, the channel width W1/the gate length L1 of the first transistor 100 of the constant current source 11 including the semiconductor device 10 is 5 μm/6 μm, and the channel width W2/the gate length L2 of the second transistor 110 is 20 μm/6 μm. The electrical characteristics of the constant current source 11 including the semiconductor device 10 in the case where N=4 and the reference channel width W3 is 4 μm are considered to be substantially the same as the electrical characteristics of the single-gate constant current source of Comparative Example 1 in which the channel length W/the gate length L is 20 μm/30 μm. However, it is considered that an area of the layout of the single-gate constant current source of Comparative Example 1 is larger than an area of the layout of the constant current source 11 including the semiconductor device 10 by, for example, about 30%.

Therefore, the constant current source 11 including the semiconductor device 10 can reduce the area of the layout compared with the constant current source of Comparative Example 1.

Next, a cross-sectional structure of the semiconductor device 10 will be described with reference to FIG. 6. FIG. 6 is a diagram showing an example in which the semiconductor device 10 is included in a display device 300. For example, the display device 300 shown in FIG. 6 is a liquid crystal display device.

For example, the display device 300 includes a first substrate 120, a TFT array layer 30, a wiring layer 40, an electrode layer 48, a first alignment film 50, a liquid crystal layer 60, a second alignment film 70, an overcoat layer 150, a color filter layer 80, and a second substrate 90.

The TFT array layer 30 and the wiring layer 40 are arranged on the first substrate 120.

The TFT array layer 30 includes a base film 160, the semiconductor film 32, a gate insulating film 33, the first conductive films 34a and 34b, an insulating film 35, the second conductive films 31a and 31b, the first openings 39a, 39b, 39c and 39d, and an organic film 38.

The base film 160 is arranged on the first substrate 120. The semiconductor film 32 is arranged on the base film 160. The semiconductor film 32 includes the semiconductor film 32a of the first transistor 100 and the semiconductor film 32b of the second transistor 110. The semiconductor film of each thin film transistor included in the display device 300 is arranged in the same layer as the semiconductor film 32. For example, although the display device 300 includes an n-type thin film transistor and a p-type thin film transistor, the first transistor 100 and the second transistor 110 are n-type thin film transistors. For example, a material forming the semiconductor film 32 is poly-silicon.

The gate insulating film 33 is arranged so as to cover the semiconductor film 32. The first conductive film 34a, the first conductive film 34b, and the input signal line 12 are arranged on the gate insulating film 33. The first conductive film 34a is the gate electrode 102 of the first transistor 100 and the gate electrode 112 of the second transistor 110 is the first conductive film 34b. In addition, the first conductive film 34a, the first conductive film 34b, and the input signal line 12 are the first conductive film. For example, a material forming the first conductive film is a metal such as titanium (Ti), aluminum (Al), copper (Cu), tungsten (W), tantalum (Ta), or an alloy thereof.

The insulating film 35 is arranged so as to cover the first conductive film 34a, the first conductive film 34b, and the input signal line 12. For example, a material forming the insulating film 35 is an inorganic insulator such as silicon nitride (SiN), silicon oxide (SiO₂), or silicon nitride oxide (SiON).

The first opening 39a opens the gate insulating film 33 and the insulating film 35, and electrically connects the semiconductor film 32a and the second conductive film 31a. For example, the first opening 39b, 39c and 39d are openings for opening the gate insulating film 33 and the insulating film 35 and electrically connecting the semiconductor film 32b and the second conductive film 31b.

Although not shown in the diagram, the TFT array layer 30 includes a second opening. The second opening is an opening for opening the insulating film 35 and electrically connecting the first conductive film and the second conductive film.

The second conductive films 31a and 31b are arranged on an upper surface of the insulating film 35, and a side surface and a bottom surface of the first opening (a side surface of the insulating film 35 and a side surface of the gate insulating film 33). The first voltage supply wiring 14 and the output signal line 16 are also arranged in the same layer as the second conductive films 31a and 31b. The same material as the first conductive film may be used for the second conductive film.

The organic film 38 is arranged so as to cover the second conductive film. For example, a material forming the organic film 38 is a polyimide-based resin or an acrylic-based resin. The organic film 38 using the polyimide-based region or acrylic-based resin can reduce unevenness when forming the film, the wiring, the transistor, or the like below the organic film 38.

A method of forming the TFT array layer 30, a structure of the transistor or the like, each film, layer, and each member may be the method and members commonly used in the technical field of the present invention.

The wiring layer 40 is arranged on the organic film 38. The wiring layer 40 includes a third conductive film (not shown in the diagram) and an insulating film 49. The insulating film 49 is arranged so as to cover the third conductive film. For example, the third conductive film is a film that forms a capacitance wiring that supplies a voltage to the capacitors of the plurality of pixels included in the display device 300. A material similar to that of the first conductive film can be used as the third conductive film, and a material similar to that of the insulating film 35 and a material similar to that of the organic film 38 can be used as the insulating film 49.

The electrode layer 48 is arranged on the insulating film 49. For example, the electrode layer 48 includes a fourth conductive film (not shown in the diagram) and an insulating film 45. The insulating film 45 is arranged so as to cover the fourth conductive film. For example, the fourth conductive film is a film that forms a wiring or the like that connects the capacitance wiring, the electrodes, power source lines, and the wiring to each other. A transparent conductive film, a thin film of a conductive metal material, or the like can be used as a material for forming the fourth conductive film. For example, the transparent conductive film is ITO (Indium Tin Oxide) or IZO (Indium Zinc Oxide). For example, the thin film of the conductive metal material is a thin film made of aluminum (Al), titanium (Ti), tungsten (W), or the like. In addition, a material similar to the material for forming the insulating film 35 and the organic film 38 can be used as a material for forming the insulating film 45.

In addition, a pixel electrode (not shown in the diagram) included in each of the plurality of pixels is arranged on the insulating film 45. For example, the pixel electrode is electrically connected to a second conductive film (not shown in the diagram) that forms the drain electrode of the transistor included in the pixel via an opening (not shown in the diagram) that opens the insulating film 45, the insulating film 49, and the organic film 38. In addition, the opening for opening the insulating film 45, the insulating film 49, and the organic film 38 may open the fourth conductive film and the third conductive film. The first alignment film 50 is applied so as to cover the plurality of pixel electrodes. The first alignment film 50 is formed of a material exhibiting lateral orientation, and the first substrate 120 is arranged on a surface facing the liquid crystal layer 60. For example, the same transparent conductive film as the material for forming the fourth conductive film can be used as the material for forming the pixel electrode. For example, a material forming the first alignment film 50 may be a polyimide-based resin or the like.

For example, sandwiching the liquid crystal layer 60 of the display device 300, the first substrate 120 side is referred to as a TFT array-side substrate, and the second substrate 90 side is referred to as the opposite-side substrate. The opposite-side substrate includes the second alignment film 70, the overcoat layer 150, the color filter layer 80, and the second substrate 90. The color filter layer 80, the overcoat layer 150, and the second alignment film 70 are arranged on the second substrate 90 in this order. For example, the color filter layer 80 includes a color filter layer that emits red, a color filter layer that emits green, and a color filter layer that emits blue. The second alignment film 70 faces the first alignment film 50 with the liquid crystal layer 60 interposed therebetween. For example, a polyimide-based resin similar to that of the first alignment film 50 may be used as a material for forming the second alignment film 70. For example, a resin of an organic material can be used as the overcoat layer 150.

Next, an example of a layout of the semiconductor device 10 when N=4 will be described with reference to FIG. 7. The layout shown in FIG. 7 is different from the layout shown in FIG. 5 in the arrangement of the semiconductor film 32a and the semiconductor film 32b in the semiconductor film 32. Other points of the layout shown in FIG. 7 are the same as the layout shown in FIG. 5. Therefore, in the description of the layout shown in FIG. 7, the same contents as the layout shown in FIG. 5 will be described as necessary.

As shown in FIG. 7, the first end 32aa and the first end 32ba are arranged so as to be positioned on different straight lines, and the second end 32ab and the second end 32bb are arranged so as to be positioned on different straight lines. In addition, part of the first end 32aa, part of the first end 32ba, part of the second end 32ab, and part of the second end 32bb are arranged so as to be positioned between the first conductive film 34a and the first conductive film 34b.

Next, an example of a layout of the semiconductor device 10 when N=1 will be described with reference to FIG. 8. The layout shown in FIG. 8 is different from the layout shown in FIG. 5 in that N=1 and in the arrangement of the semiconductor film 32a and the semiconductor film 32b in the semiconductor film 32. Other points of the layout shown in FIG. 8 are the same as the layout shown in FIG. 5. Therefore, in the description of the layout shown in FIG. 8, the same contents as those of the layout shown in FIG. 5 will be described as necessary.

As shown in FIG. 8, the channel width W1 of the first transistor 100 and the channel width W2 of the second transistor 110 are 2×W3 (reference channel width W3). In addition, in the semiconductor device 10 shown in FIG. 8, similar to the layout shown in FIG. 5, the gate length L1 of the first transistor 100 is the same as the gate length L2 of the second transistor 110.

In addition, the first end 32aa and the first end 32ba of the semiconductor device 10 shown in FIG. 8 are arranged so as to be positioned on the same straight line, and the second end 32ab and the second end 32bb are arranged so as to be positioned on the same straight line. In addition, part of the first end 32aa, part of the first end 32ba, part of the second end 32ab, and part of the second end 32bb are arranged so as to be positioned between the first conductive film 34a and the first conductive film 34b.

As described above, the semiconductor device 10 and the constant current source 11 including the semiconductor device 10 according to the first embodiment can improve the saturated current characteristics, suppress the current consumption, and reduce the layout area.

### 2. Second Embodiment

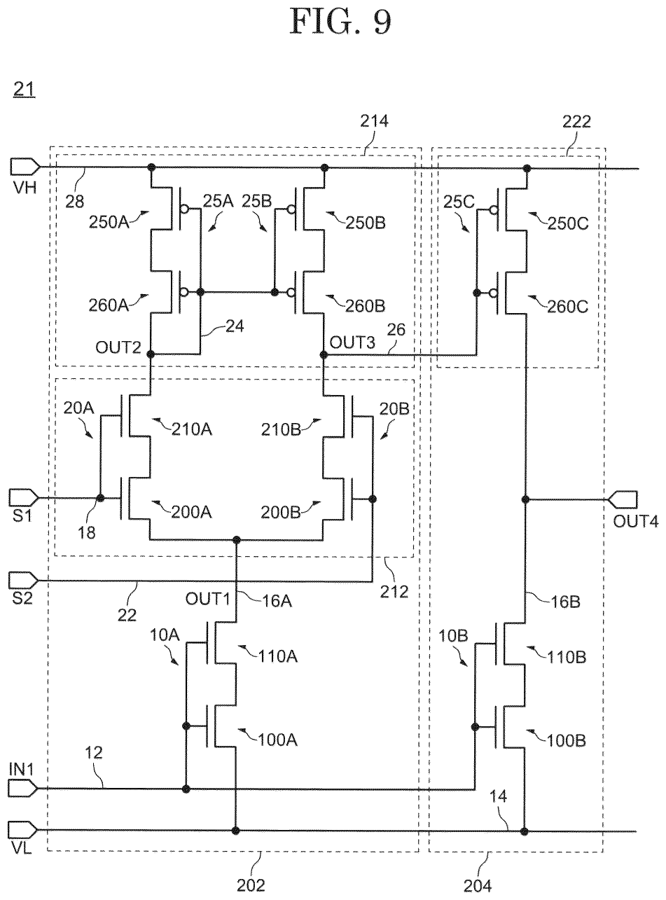

An outline of an OP-AMP 21 according to the second embodiment will be described with reference to FIG. 9. Configurations that are the same as or similar to those in FIG. 1 to FIG. 8 will be described as necessary.

FIG. 9 is a circuit diagram showing a configuration of the OP-AMP 21. The OP-AMP 21 includes a first amplifier circuit 202 and a second amplifier circuit 204. The first amplifier circuit 202 may be referred to as an input stage of the OP-AMP 21, and the second amplifier circuit 204 may be referred to as an output stage of the OP-AMP 21. In addition, although the OP-AMP 21 includes a two-stage amplifier circuit, the amplifier circuit is not limited to two stages. For example, the OP-AMP 21 may include three or more stages of amplifier circuits. The number of stages of the amplifier circuit of the OP-AMP 21 may be appropriately set according to the application and specifications of the OP-AMP 21.

The first amplifier circuit 202 includes a semiconductor device 10A, a differential amplifier unit 212, and a current mirror unit 214. The second amplifier circuit 204 includes a semiconductor device 10B and a source ground amplifier unit 222. Although details will be described later, the semiconductor device 10A and the semiconductor device 10B have the same configuration as the semiconductor device 10 described in the “first embodiment”. That is, the OP-AMP 21 includes a plurality of semiconductor devices 10. The semiconductor device 10A may be referred to as a first semiconductor device and the semiconductor device 10B may be referred to as a second semiconductor device. In addition, the configurations of the semiconductor device 10A and the semiconductor device 10B will be described as necessary.

The semiconductor device 10A includes a first transistor 100A and a second transistor 110A. The first transistor 100A and the second transistor 110A are n-type transistors. The semiconductor device 10A is one transistor having a double gate. Similar to the semiconductor device 10, for example, the first transistor 100A and the transistor 110A of the second thin film transistor are n-type thin film transistors. In addition, the semiconductor device 10A is electrically connected between the first voltage supply wiring 14 and an output signal line 16A, and a gate electrode of the semiconductor device 10A is electrically connected to the input signal line 12. The input signal IN1 is supplied to the input signal line 12, the common voltage VL is supplied to the first voltage supply wiring 14, and the output signal OUT1 is supplied to the output signal line 16A.

The differential amplifier unit 212 includes a first transistor 20A and a second transistor 20B. The first transistor 20A includes a first transistor 200A and a second transistor 210A sharing the gate electrode and are electrically connected. That is, the first transistor 20A is one transistor having a double gate. Similar to the first transistor 20A, the second transistor 20B includes a first transistor 200B and a second transistor 210B sharing the gate electrode and are electrically connected. That is, the second transistor 20B is one transistor having a double gate. The first transistor 200A, the second transistor 210A, the first transistor 200B, and the second transistor 210B are n-type thin film transistors.

The first transistor 20A is electrically connected between the output signal line 16A and a first node 24, and the gate electrode of the first transistor 20A is electrically connected to a first input signal line 18. The output signal OUT1 is supplied to the output signal line 16A, a first input signal S1 is supplied to the first input signal line 18, and an output signal OUT2 is supplied to the first node 24.

The second transistor 20B is electrically connected between the output signal line 16A and a second node 26, and a gate electrode of the second transistor 20B is electrically connected to a second input signal line 22. The output signal OUT1 is supplied to the output signal line 16A, a second input signal S2 is supplied to the second input signal line 22, and an output signal OUT3 is supplied to the second node 26.

The current mirror unit 214 includes a third transistor 25A and a fourth transistor 25B. Similar to the first transistor 20A, the third transistor 25A includes a first transistor 250A and a second transistor 260A sharing the gate electrode and electrically connected. That is, the third transistor 25A is one transistor having a double gate. Similar to the first transistor 20A, the fourth transistor 25B includes a first transistor 250B and a second transistor 260B sharing the gate electrode and electrically connected. That is, the fourth transistor 25B is one transistor having a double gate. The first transistor 250A, the second transistor 260A, the first transistor 250B, and the second transistor 260B are p-type thin film transistors.

The third transistor 25A is electrically connected between the first node 24 and a second voltage supply wiring 28, and a gate electrode of the third transistor 25A is electrically connected to the first node 24. The output signal OUT2 is supplied to the first node 24 and a power supply voltage VH is supplied to the second voltage supply wiring 28. The power supply voltage VH is, for example, a voltage VDD. The voltage VDD may be greater than the common voltage VL, for example 3 V, or may be 3.3 V, 5 V, 12 V, or 15 V. The power supply voltage VH may be appropriately set according to the application and specifications of the OP-AMP 21.

The fourth transistor 25B is electrically connected between the second node 26 and the second voltage supply wiring 28, and a gate electrode of the fourth transistor 25B is electrically connected to the first node 24. The output signal OUT2 is supplied to the first node 24, the power supply voltage VH is supplied to the second voltage supply wiring 28, and the output signal OUT3 is supplied to the second node 26.

For example, in the case where the third transistor 25A is formed with the same channel width and gate length as the fourth transistor 25B, a current flowing through the first node 24 flows to the second node 26, and the output signal OUT3 corresponding to the output signal OUT2 is output to the second node 26.

The semiconductor device 10B includes a first transistor 100B and a second transistor 110B. The first transistor 100B and the second transistor 110B are n-type transistors. The semiconductor device 10B is one transistor having a double gate. In addition, the semiconductor device 10B is electrically connected between the first voltage supply wiring 14 and an output signal line 16B, and a gate electrode of the semiconductor device 10B is electrically connected to the input signal line 12. The input signal IN1 is supplied to the input signal line 12, the common voltage VL is supplied to the first voltage supply wiring 14, and an output signal OUT4 is supplied to the output signal line 16B.

The source ground amplifier unit 222 includes a fifth transistor 25C. Similar to the fourth transistor 25B, the fifth transistor 25C includes a first transistor 250C and a second transistor 260C sharing the gate electrode and electrically connected. That is, the fifth transistor 25C is one transistor having a double gate. The first transistor 250C and the second transistor 260C are p-type thin film transistors.

The fifth transistor 25C is electrically connected between the output signal line 16B and the second voltage supply wiring 28, and the fifth transistor 25C has a gate electrode electrically connected to the second node 26. The output signal OUT3 is supplied to the second node 26, the power supply voltage VH is supplied to the second voltage supply wiring 28, and the output signal OUT4 is supplied to the output signal line 16B.

For example, in the case where the third transistor 25A is formed with the same channel width and gate length as the fourth transistor 25B, a current flowing through the first node 24 flows to the second node 26, and the output signal OUT3 corresponding to the output signal OUT2 is output to the second node 26. That is, the first amplifier circuit 202 outputs the output signal OUT3 corresponding to the output signal OUT2 to the second amplifier circuit 204. In addition, the second amplifier circuit 204 outputs the output signal OUT4 corresponding to the output signal OUT3.

In addition, the same configuration as that of the semiconductor device 10 may be applied to each of the first transistor 20A, the second transistor 20B, the third transistor 25A, the fourth transistor 25B, and the fifth transistor 25C, or part of the first transistor 20A, the second transistor 20B, the third transistor 25A, the fourth transistor 25B, and the fifth transistor 25C.

The OP-AMP 21 includes the semiconductor device 10A and is capable of flowing a stable current to the second node 26 of the first amplifier circuit 202. In addition, the OP-AMP 21 includes the semiconductor device 10B, and is capable of flowing a stable current to the output signal line 16B of the second amplifier circuit 204 and outputting the stable output signal OUT4 corresponding to the output signal OUT3. In addition, the increase in current consumption of the OP-AMP 21 can be suppressed, and the layout area of the OP-AMP 21 can be reduced.

### 3. Third Embodiment

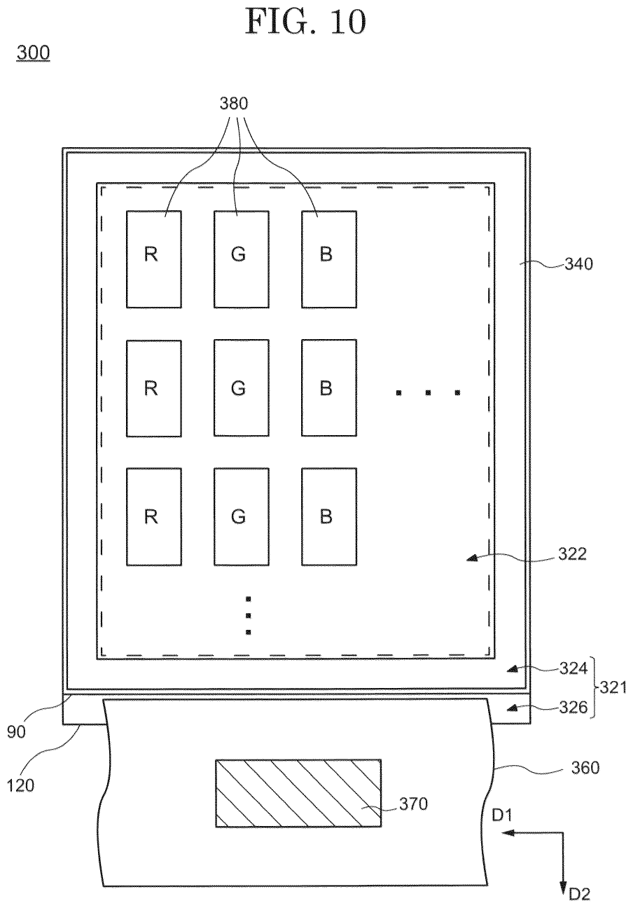

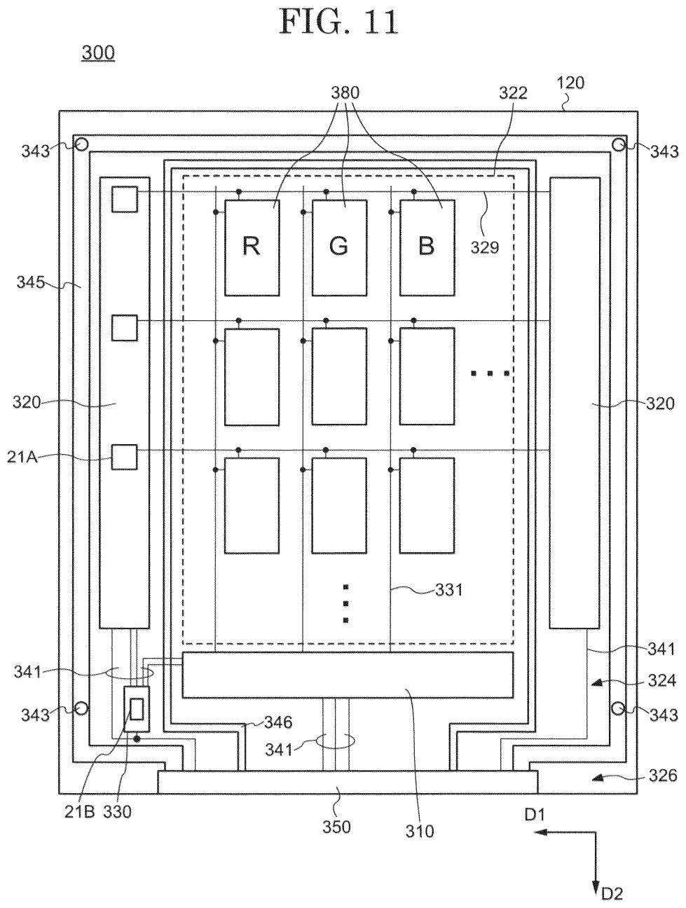

An outline of the display device 300 will be described with reference to FIG. 10 and FIG. 11. Configurations that are the same as or similar to those in FIG. 1 to FIG. 9 will be described as necessary.

FIG. 10 and FIG. 11 are top views showing a configuration of the display device 300. The display device 300 has a configuration similar to that of the display device 300 described in “1-3. Example of Layout and Cross-sectional Structure of Semiconductor Device 10”, and is a liquid crystal display device as an example. Although details will be described later, for example, configurations and functions similar to those of the OP-AMP 21 including the semiconductor device 10 are included in a control circuit 330 and a second drive circuit 320. In addition, configurations and functions similar to those of the OP-AMP 21 including the semiconductor device 10 may be included in a first drive circuit 310 or an IC chip 370.

As shown in FIG. 10, the display device 300 includes the first substrate 120, a seal part 340, the second substrate 90, a flexible printed circuit substrate 360 (FPC 360), and the IC chip 370. The first substrate 120 and the second substrate 90 are bonded together by the seal part 340. A plurality of pixels 380 is arranged in a matrix in the direction D1 and direction D2 in a display region 322 surrounded by the seal part 340. The display region 322 is a region overlapping the liquid crystal layer 60 (FIG. 6) in a plan view.

A peripheral region 321 includes a seal region 324 and a terminal region 326. The peripheral region 321 is a region around the display region 322 and surrounds the display region 322. The seal region 324 is a region around the display region 322 overlapping the seal part 340 in a plan view. The terminal region 326 is a region where the first substrate 120 is exposed from the second substrate 90 and is arranged outside the seal region 324. In addition, the outside of the seal region 324 means the outside of the region surrounded by the seal part 340. The FPC 360 is arranged in the terminal region 326. The IC chip 370 is arranged on the FPC 360 as an example. The IC chip 370 supplies a control signal for driving each pixel 380.

As shown in FIG. 11, the first drive circuit 310 is arranged parallel to the direction D1 of the display region 322. In addition, the second drive circuit 320 is arranged parallel to the direction D2 of the display region 322. The first drive circuit 310 and the second drive circuit 320 are arranged in the seal region 324 (FIG. 10).

For example, the first drive circuit 310 is a source driver and may include a multiplexer circuit for selecting a data signal. For example, the second drive circuit 320 is a gate driver circuit.

For example, an arrangement of the plurality of pixels 380 is a stripe arrangement. For example, each of the plurality of pixels 380 may correspond to a sub-pixel R, a sub-pixel G, and a sub-pixel B. One pixel may be formed of three sub-pixels. The pixel 380 is the smallest unit constituting part of an image reproduced in the display region 322. Each of the pixels 380 includes one display element (not shown in the diagram). The display element is a liquid crystal element in the example shown in FIG. 10. The color corresponding to the sub-pixel is determined by the characteristics of the liquid crystal element or a color filter (not shown in the diagram) arranged in the sub-pixel.

The sub-pixel R, the sub-pixel G, and the sub-pixel B can be configured to exhibit different colors in the stripe arrangement. For example, each of the sub-pixel R, the sub-pixel G, and the sub-pixel B may include a color filter (not shown in the diagram) that emits three primary colors of red, green, and blue. For example, the sub-pixel R may include a red color filter that emits red, the sub-pixel G may include a green color filter that emits green, and the sub-pixel B may include a blue color filter that emits blue. An arbitrary voltage or current is supplied to each of the three sub-pixels, and the display device 300 can display an image.

A plurality of data signal lines including a data signal line 331 extends in the direction D2 from the first drive circuit 310 and is connected to the plurality of pixels 380 arranged in the direction D2. A plurality of scanning signal lines including a scanning signal line 329 extends in the direction D1 from the second drive circuit 320 and is connected to the plurality of pixels 380 arranged in the direction D1.

A terminal part 350 is arranged in the terminal region 326. The terminal part 350 and the first drive circuit 310 are connected by a connection wiring 341. Similarly, the terminal part 350 and the second drive circuit 320 are connected by the connection wiring 341. When the FPC 360 is connected to the terminal part 350, an external device to which the FPC 360 is connected and the display device 300 are connected, and for example, a signal from the external device is supplied to the IC chip 370, the first drive circuit 310, the second drive circuit 320, the control circuit 330, and each pixel 380. The display device 300 drives each pixel 380 arranged in the display device 300 using the signal from the external device and control signals generated by the IC chip 370, the first drive circuit 310, and the second drive circuit 320.

For example, the control circuit 330 includes an OP-AMP 21B including the semiconductor device 10. The control circuit 330 is capable of shaping the signal from the external device, based on the OP-AMP 21B and generating a stable voltage. As a result, for example, the control circuit 330 can supply the shaped signal and stable voltage to the first drive circuit 310 and the second drive circuit 320.

For example, the second drive circuit 320 includes an OP-AMP 21A including the semiconductor device 10. The second drive circuit 320 is capable of shaping the signal from the external device based on the OP-AMP 21A and generating a stable voltage. As a result, the second drive circuit 320 can supply the shaped signal and the stable voltage to the circuit inside the second drive circuit 320 and can operate stably using the shaped signal and the stable voltage. In addition, for example, the second drive circuit 320 may supply the shaped control signal to the scanning signal line 329. In other words, the OP-AMP 21A is electrically connected to the scanning signal line 329 and is capable of supplying the shaped control signal to the scanning signal line 329 and the plurality of pixels 380 electrically connected to the scanning signal line 329.

For example, the first drive circuit 310 may include the constant current source 11 (shown in FIG. 2) including the semiconductor device 10. The first drive circuit 310 may shape the data signal and the control signal supplied from the IC chip 370 based on the constant current source 11. As a result, the first drive circuit 310 can supply the shaped control signal to the circuit inside the first drive circuit 310 and can operate stably using the shaped control signal. For example, the first drive circuit 310 may supply the shaped data signal to the data signal line 331.

For example, each of the plurality of pixels 380 includes a transistor (not shown in the diagram), a liquid crystal element (not shown in the diagram), and a capacity element (not shown in the diagram). The liquid crystal element and the capacity element are electrically connected to the transistor. The transistor is electrically connected to the scanning signal line 329 and the data signal line 331. For example, the capacity element is electrically connected between the pixel electrode and a capacitance wiring 346. For example, the liquid crystal element includes a pixel electrode (not shown in the diagram), a common electrode (not shown in the diagram), and a liquid crystal molecule included in the liquid crystal layer 60. The common electrode is electrically connected to a common wiring 345. For example, the pixel electrode is arranged on the insulating film 45 (FIG. 6). The wiring layer 40 (FIG. 6) includes the capacitance wiring 346 and the electrode layer 48 (FIG. 6) includes the common electrode and the common wiring.

For example, the control circuit 330 supplies a common voltage to the capacitance wiring 346 and the common wiring 345. For example, the common voltage may be a voltage between a voltage of a positive voltage amplitude of the data signal and a voltage of a negative voltage amplitude of the data signal, and may be a voltage that is a reference of the voltage amplitude, may be 0 V, and may be a ground voltage. Since the common wiring 345 is electrically connected to the common electrode via a plurality of connection parts 343, the liquid crystal element is electrically connected to the common electrode. The first drive circuit 310, the second drive circuit 320, and the control circuit 330 can change the orientation status of the liquid crystal molecules by supplying a current or voltage to each of the pixel electrode and the common electrode. As a result, the display device 300 can display an image.

As described above, the display device 300 includes the constant current source including the semiconductor device 10, and can perform stable operation using the constant current source including the semiconductor device 10.

Various configurations of the semiconductor device, the constant current source including the semiconductor device, the OP-AMP including the semiconductor device, and the display device including the OP-AMP can be appropriately combined as long as no contradiction is caused. In addition, the various configurations of the semiconductor device, the constant current source including the semiconductor device, the OP-AMP including the semiconductor device, and the display device including the OP-AMP can be replaced as appropriate as long as no contradiction is caused. The addition, deletion, or design change of components, or the addition, deletion, or condition change of processes as appropriate by those skilled in the art based on the semiconductor device, the constant current source including the semiconductor device, the OP-AMP including the semiconductor device, and the display device including the semiconductor device are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a first transistor including a first gate electrode; and
a second transistor including a second gate electrode electrically connected to the first gate electrode and a source electrode electrically connected to a drain electrode of the first transistor,
wherein
the first transistor includes a first channel width and a first gate length,
the second transistor includes a second channel width and a second gate length, and
a value obtained by dividing the second channel width by the second gate length is greater than or equal to a value obtained by dividing the first channel width by the first gate length.

2. The semiconductor device according to claim 1,
wherein the first gate length is the same as the second gate length.

3. The semiconductor device according to claim 2,
wherein the second channel width is N times the first channel width.

4. The semiconductor device according to claim 1, further comprising an active layer,
wherein the active layer includes one pattern having the first channel width and the second channel width.

5. The semiconductor device according to claim 4,
wherein the active layer includes a poly-silicon.

6. The semiconductor device according to claim 1,
wherein a source electrode of the first transistor is electrically connected to a voltage supply line, and is supplied with a ground voltage from the voltage supply line.

7. An OP-AMP comprising:
a plurality of the semiconductor devices according to claim 1.

8. The OP-AMP according to claim 7,
wherein
the plurality of the semiconductor devices includes a first semiconductor device,
a first signal is input to the first semiconductor device,
a first amplifier circuit includes the first semiconductor device,
a differential amplifier unit is electrically connected to the first semiconductor device, and
a current mirror unit is electrically connected to the differential amplifier unit.

9. The OP-AMP according to claim 8,
wherein
the plurality of the semiconductor devices includes a second semiconductor device,
the first signal is input to the second semiconductor device,
the second semiconductor device is different from the first semiconductor device, and
a second amplifier circuit is electrically connected to the first amplifier circuit and includes the second semiconductor device and a source ground amplifier unit electrically connected to the second semiconductor device.

10. A display device comprising:
the OP-AMP according to claim 9; and
a plurality of pixels electrically connected to the OP-AMP.
